(19) United States
(12) Patent Application Publication
(10) Pub. No.: US 2012/0313213 A1
(43) Pub. Date: Dec. 13, 2012

(54) POLYGON SHAPED POWER AMPLIFIER CHIPS

(75) Inventors: Paul M. Head, Dedham, MA (US); Michael T. Borkowski, Bedford, NH (US); Robert B. Hallock, Newton, NH (US)

(73) Assignee: Raytheon Company, Waltham, MA (US)

(21) Appl. No.: 13/154,953

(22) Filed: Jun. 7, 2011

(51) Int. Cl. H01L 27/088

(52) U.S. Cl. 257/499; 257/E27.06

(57) ABSTRACT

A semiconductor structure having: a wafer; and a plurality of chips disposed on the wafer, each one of the chips having a linear array of a plurality of transistors, the linear array being at an oblique angle with respect to grid lines in the wafer separating the chips. Each one of the transistors has a plurality of parallel control electrodes extending longitudinally along an axis perpendicular to the axis along which the plurality of transistors is distributed. A matching circuit is disposed on the integrated circuit chip between a corner of the integrated circuit chip and the plurality of transistors.

### TECHNICAL FIELD

This disclosure relates generally to semiconductor integrated circuit chips and more particularly to polygon shaped power amplifier semiconductor integrated circuit chips.

### BACKGROUND

As is known in the art, Radio Frequency (RF) power amplifiers have a wide range of applications. One such power amplifier is a multi-stage power amplifier. An example of one multi-stage power amplifier is described in U.S. Pat. No. 6,232,840, issued May 12, 2001 inventors Teeter, et al., assigned to the same assignee as the present invention.

As is also known in the art, the cost of RF power amplifiers (PAs) fabricated on compound semiconductor wafers is directly proportional to the integrated circuit chip area of the amplifier. Typically the size of the PA is determined by two factors: The x-dimension is related to the number of gain stages and the y-dimension is determined by the total field-effect transistor (FET) periphery of the final stage.

Traditional techniques used to reduce integrated circuit chip area of power amplifiers involve shrinking the elements within the PA. Transistors (or individual transistor gate fingers) can be moved closer together to reduce the y-dimension; this will however result in negative thermal effects. The x-dimension can be reduced by squeezing circuit components closer to one another. This approach will necessarily incur more loss and increase the opportunity for RF coupling; both will degrade the performance of the PA.

### SUMMARY

In accordance with the disclosure, a semiconductor structure is provided having: a polygon shaped semiconductor integrated circuit chip; and a plurality of transistors disposed on the integrated circuit chip and distributed along an axis making an oblique angle with respect to an axis passing through a side of the integrated circuit chip. In one embodiment, a semiconductor structure is provided having: a polygon shaped semiconductor integrated circuit chip; and a plurality of transistors disposed on the integrated circuit chip and distributed along an elongated dimension of the polygon.

In one embodiment, each one of the transistors has a plurality of parallel control electrodes extending longitudinally along an axis perpendicular to the axis along which the plurality of transistors is distributed.

In one embodiment, each one of the transistors in the second plurality of transistors has a plurality of parallel control electrodes extending longitudinally along an axis perpendicular to the axis along which the plurality of transistors is distributed.

In one embodiment, a matching circuit is disposed on the integrated circuit chip between a corner of the integrated circuit chip and the first-mentioned plurality of transistors.

In one embodiment, a second matching circuit is disposed between an opposing corner of the integrated circuit chip and the second plurality of transistors.

In one embodiment, a third matching circuit disposed between the first-mentioned pluralities of transistors and the second plurality of transistors.

In one embodiment, the angle is forty-five degrees.

In one embodiment, a semiconductor wafer is provided having a truncated circular peripheral portion terminating in a flat peripheral edge portion, comprising: a plurality of integrated circuit chips disposed within an array of intersecting scribe lines, such scribe lines being at an oblique angle with respect to the flat peripheral edge portion of the wafer.

In one embodiment, a semiconductor structure is provided, such structure comprising: a wafer; and a plurality of chips disposed on the wafer, each one of the chips having a linear array of a plurality of transistors, the linear array being at an oblique angle with respect to grid lines in the wafer separating the chips.

With such an arrangement, the integrated circuit chip scribe lines (i.e., grid) is at an oblique angle with respect to the axis along which the plurality of transistors are distributed while leaving all other circuit elements in place. By this rotation, the predetermined y-dimension of the integrated circuit chip is now aligned between corners of the grid, the result is an integrated circuit chip area that is significantly smaller than that of a prior art integrated circuit chip. In utilizing this technique, the transistors themselves are allowed to remain the same dimensions which results in no additional thermal effects due to heat spreading. Traditional methods to reduce size in the y-dimension call for reducing the spacing between control electrode (i.e., gate fingers with a FET and base electrodes with a BJT) which reduces the area available for dissipation of thermal energy; thus increasing the channel temperature and reducing the performance of the device. Power amplifiers naturally fit well along an elongated dimension of a polygon shape due to the power splitting/combining which occurs within the impedance matching networks. These networks are commonly referred to as the output matching network (OMN), input matching network (IMN), and inter-stage matching networks (ISMN). Traditional rectangular array of PAs (i.e., an array of rows and columns of PAs) PAs contain under-utilized or wasted space in the corners of the integrated circuit chip, particularly above and below the IMN. The rotated grid eliminates this space without compromising the critical areas of the matching networks, which results in reduced size of the PA, without compromising performance. Conventional methods for reducing size in the x-dimension call for compacting of the matching networks. Compacting of these networks to inevitably leads to added electrical loss, reduced bandwidth, and/or non-optimal matching conditions.

The details of one or more embodiments of the disclosure are set forth in the accompanying drawings and the description below. Other features, objects, and advantages of the disclosure will be apparent from the description and drawings, and from the claims.

### DESCRIPTION OF DRAWINGS

FIG. 1 is a top view of a semiconductor wafer having a plurality of semiconductor integrated circuit chips according to the disclosure;

FIGS. 1A-1C are side cross sectional views of a portion of the wafer of FIG. 1 at various stages in the separation of the chips;

FIG. 2 is a top view of an exemplary one of the integrated circuit chips of FIG. 1, such integrated circuit chip having a multi-stage power amplifier, each stage having a plurality of transistors;

FIG. 3 is a top view of a typical one of the transistors adapted for fabrication on the integrated circuit chip of FIG. 2;

FIG. 4 is a side-by-side comparison of an integrated circuit chip according to the PRIOR ART and the integrated circuit chip of FIG. 2;

FIG. 5 is a side-by-side comparison of a wafer according to the PRIOR ART and the wafer of FIG. 1;

FIG. 6 is a plan view of a semiconductor wafer having a hexagonal crystallographic structure and having a plurality of chips therein defined by scribe lines formed on the wafer in accordance with the disclosure;

FIGS. 7A-7C are side cross sectional views of a portion of the wafer of FIG. 6 at various stages in the separation of the chips;

FIG. 8 is a diagram of a hexagonal crystal structure, such diagram being useful in understanding crystallographic axis, directions and planes of the structures;

FIG. 9 is a top view of an exemplary one of the integrated circuit chips of FIG. 6, such integrated circuit chip having a multi-stage power amplifier, each stage having a plurality of transistors;

FIG. 9A is a perspective view of the exemplary one of the chips of FIG. 9;

FIG. 10 is a diagram showing the scribe lines formed in the wafer of FIG. 6 relative to crystallographic axis of the wafer in accordance with the disclosure;

FIG. 11 is a plane view of a semiconductor wafer having a hexagonal crystallographic structure and having a plurality of chips therein defined by scribe lines formed on the wafer in accordance with another embodiment of the disclosure;

FIG. 12 is a top view of an exemplary one of the integrated circuit chips of FIG. 11, such integrated circuit chip having a multi-stage power amplifier, each stage having a plurality of transistors; and

FIG. 13 is a diagram showing the scribe lines formed in the wafer of FIG. 11 relative to crystallographic axis of the wafer in accordance with the disclosure. Like reference symbols in the various drawings indicate like elements.

### DETAILED DESCRIPTION

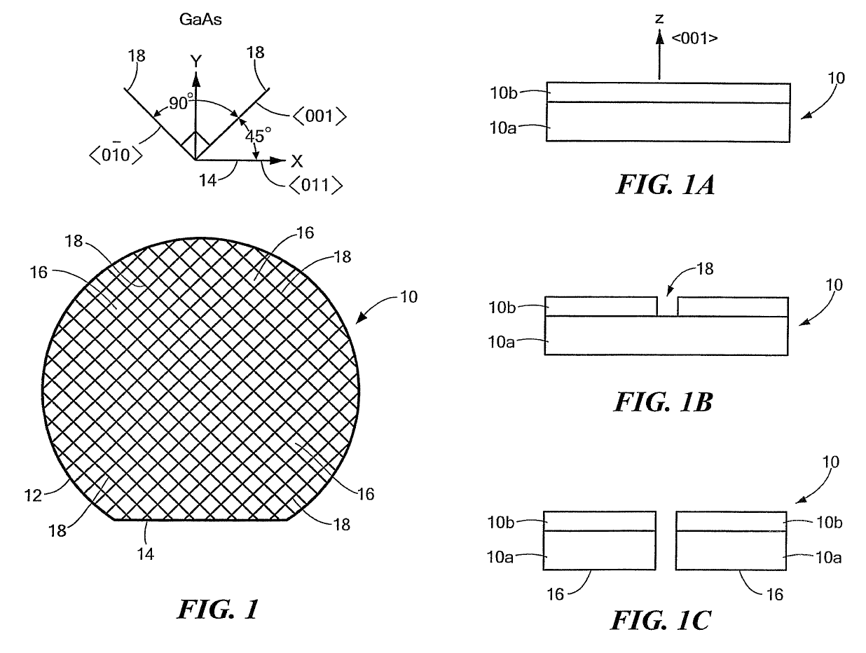

Referring now to FIG. 1, a semiconductor wafer 10 includes a cubic substrate, 10a (FIG. 1A) here a cubic, single crystal substrate of, for example, silicon or III-V material, (such as GaAs, InP, etc), here GaAs, and an epitaxial layer 10b grown along the <001> axis on the surface of the substrate 10a (such surface being in the {100} plane using any convention technology. Also shown in FIG. 1 is a set of, in this example, orthogonal axis labeled the X-axis and the Y-axis, as indicated; here with the flat edge portion 14 is along the X-axis wherein one set of the scribe lines 18 are 45 degrees with respect to the X-axis and the other set of scribe lines 18 are 45 degrees with respect to the Y axis. Here, with the cubic structure 10 includes an epitaxial layer grown in any conventional manner along the <001> crystallographic axis, such axis being perpendicular to the surface of the wafer.

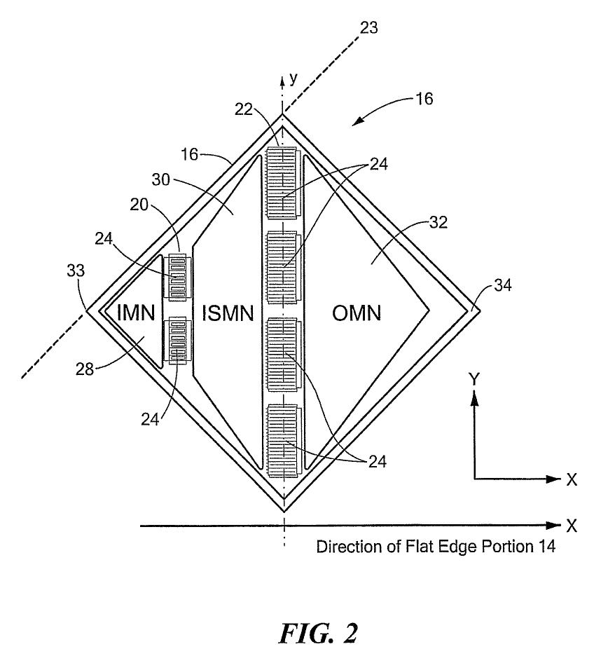

More particularly, it is noted that the wafer 10, here GaAs, is shown having a truncated circular peripheral portion 12 terminating in a flat peripheral edge portion 14. The flat portion 14 is typically long a particular crystallographic axis of the semiconductor wafer, here along the <011> direction. The wafer 10 has formed therein a plurality (here an array of rows and columns) of chips 16 (each one of the chips 16 having formed therein an integrated circuit, here for example, a power amplifier) to be described in more detail in connection with FIG. 2. The chips are defined by an array of scribe lines 18, such scribe lines 18 being at an oblique angle, here 45 and 135 degrees with respect to the X axis (i.e., at 45 and 135 degrees with respect to the <011> crystallographic axis of the substrate 10a) and therefore are at a ninety degree angle with respect to each other; i.e., the scribe lines 18 are along the <0 1̅0> and <001> crystallographic axes of the cubic substrate 10a.

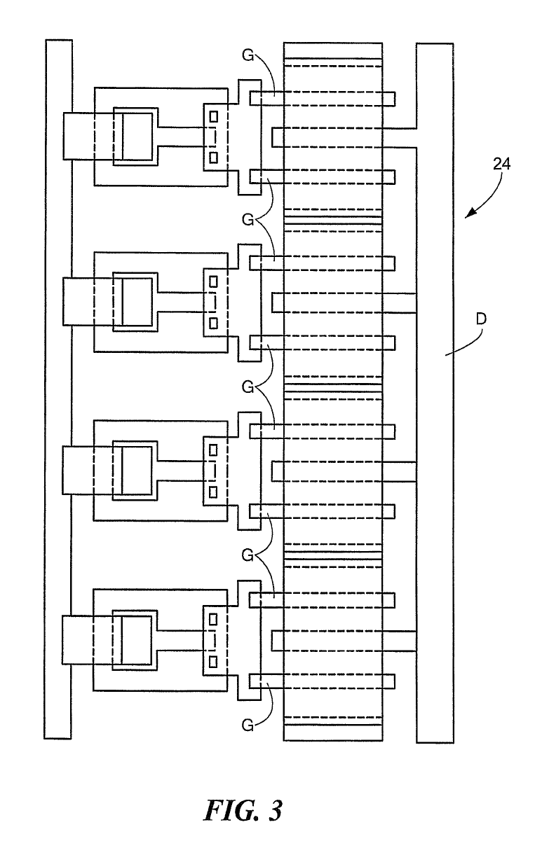

Each one of the integrated circuit chips 16, here a polygon shaped semiconductor integrated circuit chip is identical in construction, an exemplary one thereof, here a square or rectangular shaped chip, being shown in FIG. 2. It is noted that the sides of the integrated circuit chip 16 are at 45 degrees to the X-Y axis of FIG. 1. Each one of the integrated circuit chip 16 includes a plurality of serially or cascade coupled sets, here two sets 20, 22 of transistors 24, here for example, FETs 24 (a typical finger-like gate transistor structure, here the structure described in U.S. Pat. No. 6,232,840 being shown in FIG. 3) arranged to provide a multi-stage, here a two stage power amplifier having an input matching circuit or network (IMN) 28 (FIG. 2), which would typically include a power divider circuit distributing a signal at an input to the control electrode, here gate electrodes, G, of a first stage (i.e., set 20) of the transistors; an inter-stage matching circuits or networks (ISMN) 30 which would typically include a second power divider circuit distributing power at the output (here, drain electrode, D) of the first stage to inputs (here, control electrodes (gate electrodes, G)) of the second stage; and an output matching circuit or network 32 (OMN) which would typically include a power combiner combing power at the drain electrode, D, of the second stage (i.e., set 22) to output of the amplifier. It should be understood that more than two stages may be used. In such case, more gain stages comprising additional pluralities of transistors are disposed on the integrated circuit chip and distributed parallel to the axis along which the above-described plurality of transistors is distributed. Each one of the transistors in the additional pluralities of transistors would also have a plurality of parallel control electrodes extending longitudinally along an axis perpendicular to the axis along which the plurality of transistors is distributed.

Each one of the two stages 20, 22 each includes a plurality of the transistors 24, the transistors 24 in each set 20, 22 being distributed along an axis, here indicated as the Y-axis. The Y-axis is, as noted above, at an oblique angle, here 45 degrees, to a pair of opposing sides of the integrated circuit chip. Thus, the plurality of transistors is disposed on the integrated circuit chip and distributed along an axis, i.e., the Y axis, making an oblique angle with respect to an axis 23 passing through a side of the integrated circuit chip. Thus, the plurality of transistors is disposed on the integrated circuit chip along an elongated dimension of the chip.

Here, the first stage 20 has two of the FETs 24 and the second stage 22 includes four of the FETs 24. In each stage 20, 22, the FETs 24 therein include a plurality of finger-like control electrodes, here finger-like gate electrodes, G, (FIG. 3) which extend in parallel longitudinally along an axis perpendicular to the Y-axis along which the plurality of transistors 24 is distributed (i.e., here the finger-like gate electrodes G extend long the X-axis). It shown be noted that the power-handling requirement of the transistors in set 22 is greater than the power-handling requirement of the transistors in set 20. Therefore, the size of the transistors in set 22 is larger than the transistors in set 20.

The input-matching network (IMN) 28 is disposed on the integrated circuit chip between a corner 33 of the integrated circuit chip 16 and the plurality of transistors in the input stage (i.e., set 20). The output-matching network (OMN) 32 is disposed between an opposing corner 34 of the integrated circuit chip and the plurality of transistors in the second stage (i.e., set 22).

After forming the integrated circuits in the chips 18, the scribe lines 18 are formed in the epitaxial layer 10b as shown in FIG. 1A using any conventional technique. The chips 16 are then separated one from the other by typically by mechanically cutting along the scribe lines 18 through the underlying portions of the substrate 10a.

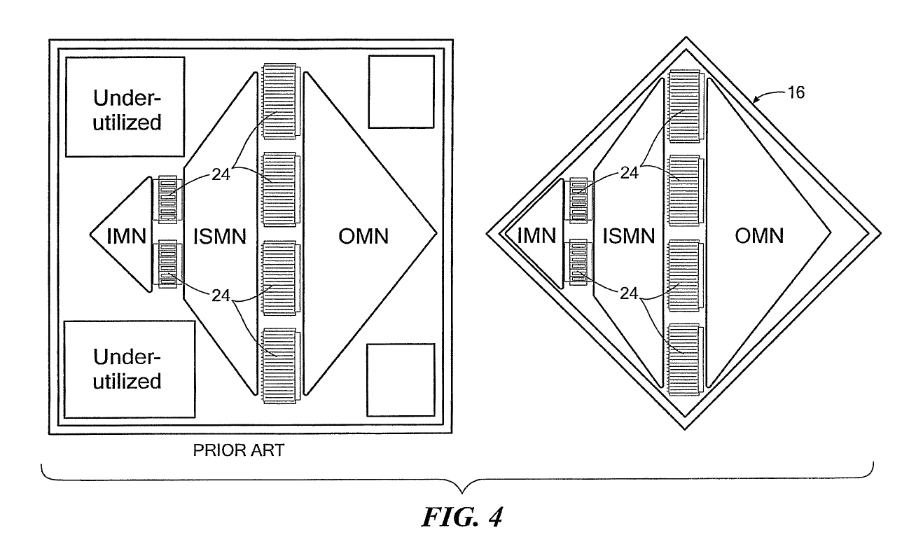

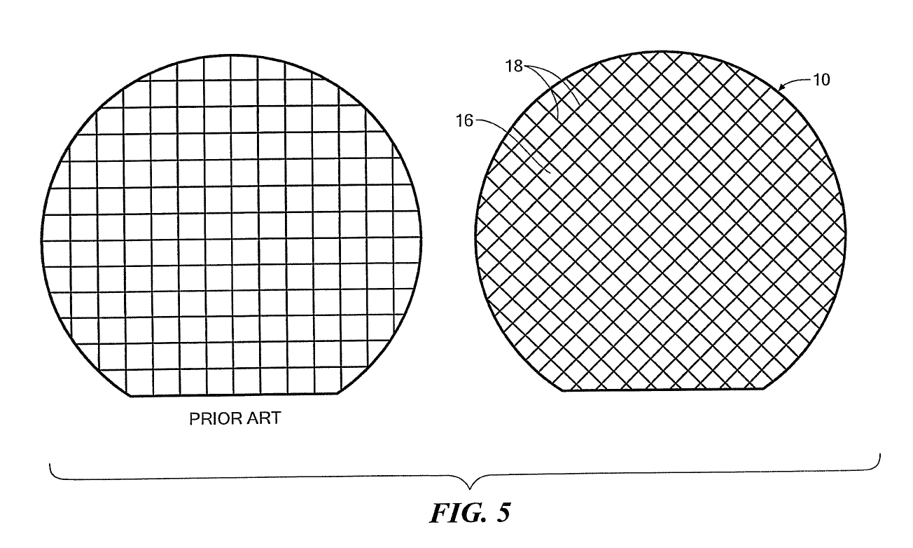

FIG. 5 compares the according to the PRIOR ART wafer with the wafer according to the disclosure side-by-side and FIG. 4 compares the PRIOR ART integrated circuit chip and with the integrated circuit chip 10 according to the disclosure side-by-side. Note that the integrated circuit chip 16 according to the disclosure appears diamond-shaped when viewed with the Y-axis oriented in the vertical direction. Note that there are significantly more integrated circuit chips 16 with the present disclosure because each integrated circuit chip 16 is significantly smaller than the area of the PRIOR ART integrated circuit chip.

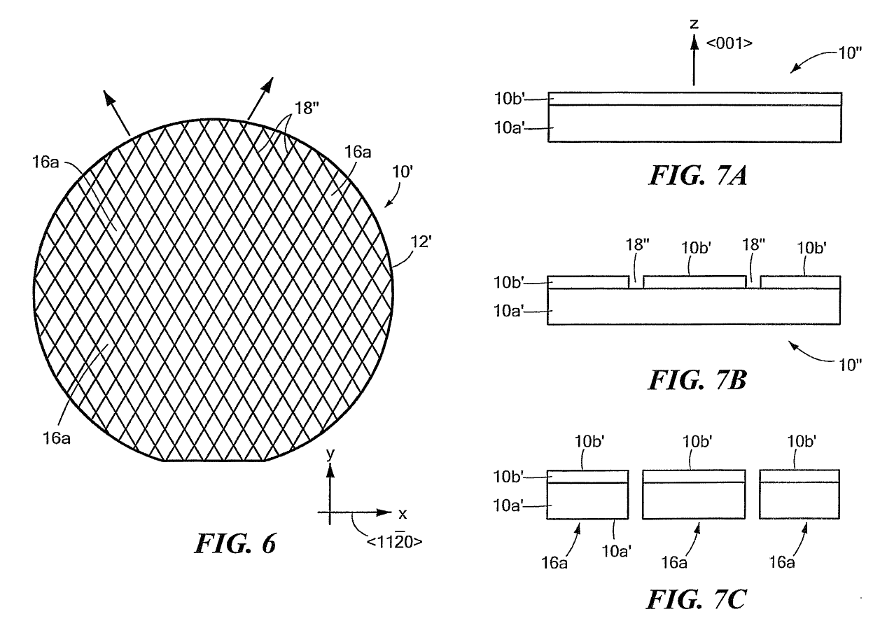

Referring now to FIG. 6, a semiconductor wafer 10′ is shown. Here the wafer 10′ has a hexagonal crystal substrate 10a′ (SiC) with an epitaxial layer 10b′ formed on the surface thereof (FIG. 7A). Here, the epitaxial layer 10b′ is GaN and may have additional epitaxial layers such as AlGaN combined with GaN layer; in either case, the additional layers and/or the GaN are referred to herein collectively as epitaxial layer 10′b.

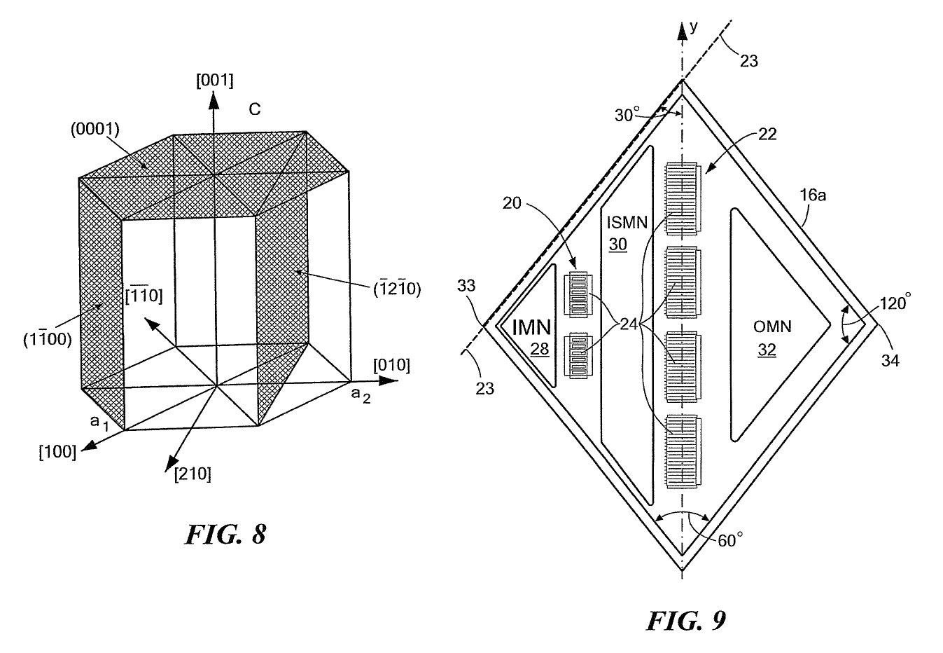

It is first noted that hexagonal wafers such as GaN and SiC are typically cut perpendicular to the c-axis as shown in FIG. 8, so that the crystallographic axes in the plane of the wafer are oriented at 60° angles, rather than 90° angles, as shown in FIG. 8. More particularly, as described in “Elements of X-Ray Diffraction” by B. D. Cullity, Addison-Wesley 1978, three vectors, a1, a2, & c are sufficient to express crystallographic directions, but an additional vector a3 is commonly used in hexagonal systems as shown. Crystallographic directions and planes are commonly identified using Miller (hkl) or Miller-Bravais (hkil) indices where [hkl] or [hkil] is a direction, <hkl> or <hkil> is a “form” of symmetrically related directions, (hkl) or (hkil) is a plane, and {hkl} or {hkil} is a “form” of symmetrically related planes.

Despite the fact that the crystallographic axes in GaN and SiC are hexagonal and oriented at 60° and 120° angles, MMIC circuits are traditionally laid out in rectilinear patterns. This precludes the use of “scribe and break” techniques used with cubic structures to give very smooth edges on GaN die (i.e., chips), because the preferred natural cleavage planes for both GaN and the underlying SiC substrate are not aligned with the “streets” or scribe lines that separate MMIC die in the layout. The consequence of this misalignment of MMIC layout and scribe lines with the crystallographic cleavage planes in GaN and SiC is that the MMIC die must be singulated (i.e., separated) with a mechanical sawing process which is time consuming, may damage the material, requires wider streets, and results in die with rough edges. The rough edges are particularly undesirable for high frequency applications that have tight tolerances on MMIC dimensions.

Thus, the surface of the wafer 10′ (FIG. 6) is in the X-Y plane here the {0001 } crystallographic plane and the epitaxial layer 10b′ is grown along the Z here <0001> crystallographic axis. The wafer 10′ is also has a truncated circular peripheral portion 12′ along the X axis (i.e., here truncated along the <11 2̅0> crystallographic axis, here along the X axis. An integrated circuit, such as the power amplifier 24 described above, is formed in the epitaxial layer 10b′; one integrated circuit for each chip 16a to be obtained from the wafer 10′.

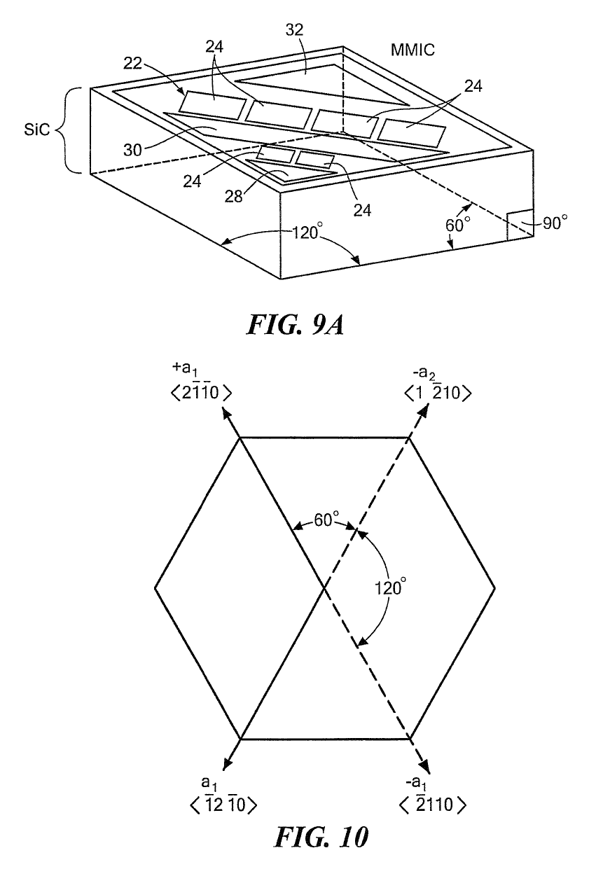

Each one of the integrated circuit chips 16a, is identical in construction, an exemplary one thereof, here a parallelogram, being shown in FIG. 9. It is noted that the sides of the integrated circuit chip 16a are at 60 degrees and 120 degrees, as indicated.

Next, the integrated circuit chips 16a are formed by etching scribe lines 18″ through the epitaxial layer 10b′ as indicated in FIG. 7B. More particularly, the scribe lines 18″ (FIGS. 6 and 7B) are along two of the crystallographic axis directions (FIG. 10): here, the <2 1̅ 1̅0> axis direction and the < 1̅2 1̅0> axis direction, as indicated. It is noted that these directions are at 60 degree and 120 degree angles, as indicated.

After scribe lines 18′ are formed through the epitaxial layer 10b′ (FIG. 7B) along two of the three crystallographic axis: here, the <2 1̅ 1̅0> axis and the < 1̅2 1̅0> axis, the chips 16a; are separated one from the other by, for example, any conventional scribe and break technique cutting along the scribe lines 18′ through the underlying portions of the substrate 10a′ (FIG. 7C); an exemplary one of the chips 18′ being shown in FIGS. 9 and 9A. Here, for example, the scribe lines 18′ are formed with a diamond tip (although other methods such as etching or laser cutting may be used) and the wafer is cleaved along the scribe lines 18′ to singulate (i.e., separate).

It is noted that by cutting along the <2 1̅ 1̅0> axis, the < 1̅2 1̅0> axis and the < 1̅ 1̅20> axis the sides of the chips 16a′ are in the {10 1̅0} plane form (FIG. 6) thereby providing the parallelogram shaped chips 16a with smooth, mirror-like edges.

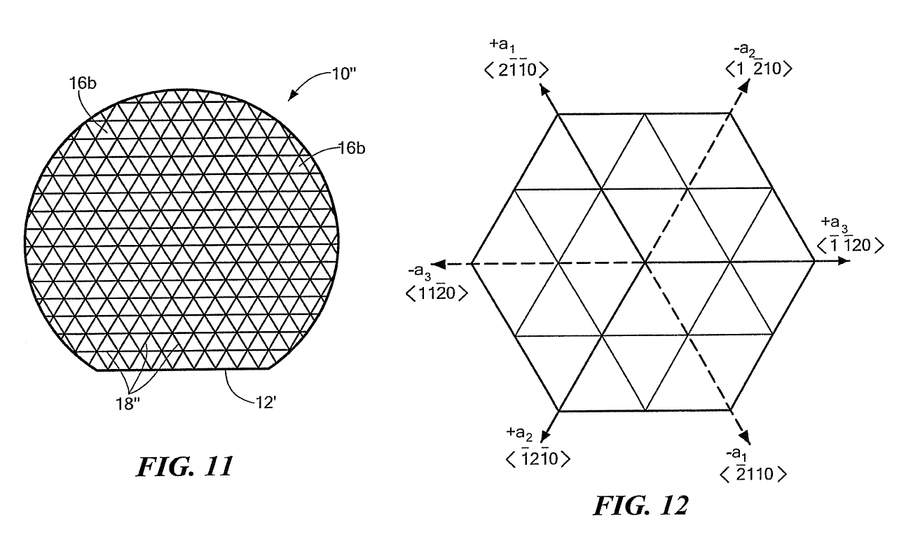

Referring now to FIG. 11, a wafer 10″ is shown. Here the wafer 10″ has a hexagonal crystal substrate (e.g., SiC) with an epitaxial layer formed on the surface thereof as described above in connection with FIG. 8A. Thus, the surface of the wafer 10″ is in the X-Y plane here the {0001} crystallographic plane and the epitaxial layer 10b′ is grown along the Z here <0001> crystallographic axis. The wafer 10″ is also has a truncated circular peripheral portion 12′ along the X axis (i.e., here truncated along the <11 2̅0> crystallographic axis, here along the X axis. An integrated circuit, such as the power amplifier 24 (FIG. 3) is (except for the OMN) formed in the epitaxial layer 10b; one integrated circuit for each chip 16b to be obtained from the wafer 10″.

Each one of the integrated circuit chips 16b, is identical in construction, an exemplary one thereof, here an equilateral triangular shaped chip, being shown in FIG. 11.

Next, equilateral triangular shaped integrated circuit chips 16b are formed by etching scribe lines 18″ though the epitaxial layer 10b′.

More particularly, the scribe lines 18′ are along three crystallographic axis directions: the <2 1̅ 1̅0> axis, the < 1̅2 1̅0> axis and the < 1̅ 1̅20>axis, as indicated in FIG. 12. It is noted that the direction of the <2 1̅ 1̅0> axis and the direction of the axis < 1̅2 1̅0> form complimentary angles of 60 and 120 degrees; and the direction of the < 1̅2 1̅0> axis and the direction of the< 1̅ 1̅20>axis form complimentary angles of 60 and 120 degrees, and the direction of the <2 1̅ 1̅0> axis and the direction of the < 1̅ 1̅20>axis form complimentary angles of 60 and 120 degrees. Thus, the scribe lines 18′ are at 60 degree angles

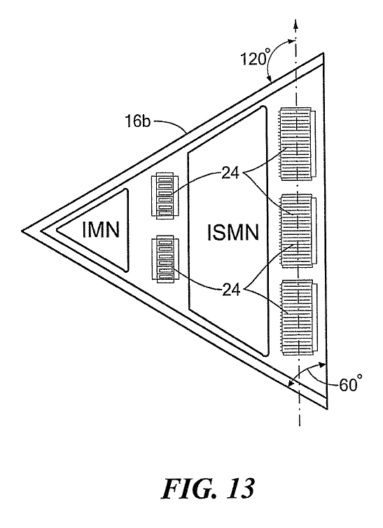

After scribe lines 18″ are formed through the epitaxial layer 10b′ along the three crystallographic axis: the <2 1̅ 1̅0> axis, the < 1̅2 1̅0> axis and the < 1̅ 1̅20> axis, the equilateral triangular shaped chips 16b; are separated one from the other by, for example, any conventional scribe and break technique cutting along the scribe lines 18″ though the underlying portions of the substrate 10a′; an exemplary one of the chips 16b being shown in FIG. 13. It is noted that by cutting along the <2 1̅ 1̅0> axis, the < 1̅2 1̅0> axis and the < 1̅ 1̅20> axis the sides of the chips 18b are in the {10 1̅0} plane form thereby providing the triangular shaped chips 18 with smooth, mirror-like edges.

It is noted that with both the triangular shaped chips and the parallelogram shaped chips, the transistors are aligned along an axis at an obtuse angle with respect to a side of the chip; and thus the transistors are distributed along an elongated dimension of the polygon (i.e., the triangle or the parallelogram).

A number of embodiments of the disclosure have been described. Nevertheless, it will be understood that various modifications may be made without departing from the spirit and scope of the disclosure. For example, a single stage or more than two stages may be used. Further, the number of transistors in each stage may be greater or less than the number described above. Accordingly, other embodiments are within the scope of the following claims.

What is claimed is:

1. A semiconductor structure, comprising:
a polygon shaped semiconductor integrated circuit chip; and
a plurality of transistors disposed on the integrated circuit chip and distributed along an axis making an oblique angle with respect to an axis passing through a side of the integrated circuit chip.

2. The semiconductor structure recited in claim 1 wherein each one of the transistors has a plurality of parallel control electrodes extending longitudinally along an axis perpendicular to the axis along which the plurality of transistors is distributed.

3. The semiconductor structure recited in claim 1 including a matching circuit disposed on the integrated circuit chip between a corner of the integrated circuit chip and the plurality of transistors.

4. The semiconductor structure recited in claim 2 including a matching circuit disposed on the integrated circuit chip between a corner of the integrated circuit chip and the plurality of transistors.

5. The semiconductor structure recited in claim 1 including a second plurality of transistors disposed on the integrated circuit chip and distributed parallel to the axis along which the first-mentioned plurality of transistors are distributed.

6. The semiconductor structure recited in claim 5 wherein each one of the transistors in the second plurality of transistors has a plurality of parallel control electrodes extending longitudinally along an axis perpendicular to the axis along which the plurality of transistors is distributed.

7. The semiconductor structure recited in claim 5 including a matching circuit disposed on the integrated circuit chip between a corner of the integrated circuit chip and the first-mentioned plurality of transistors.

8. The semiconductor structure recited in claim 6 including a matching circuit disposed on the integrated circuit chip between a corner of the integrated circuit chip and the first-mentioned plurality of transistors.

9. The semiconductor structure recited in claim 7 including a second matching circuit disposed between another corner of the integrated circuit chip and the plurality of transistors.

10. The semiconductor structure recited in claim 8 including a second matching circuit disposed between another corner of the integrated circuit chip and the second plurality of transistors.

11. The semiconductor structure recited in claim recited in claim 9 including a third matching circuit disposed between the first-mentioned plurality of transistors and the second plurality of transistors.

12. The semiconductor structure recited in claim 10 including a third matching circuit disposed between the first-mentioned plurality of transistors and the second plurality of transistors.

13. The semiconductor structure recited in claim 1 wherein the polygon is a parallelogram.

14. The semiconductor structure recited in claim 2 wherein the polygon is a parallelogram.

15. The semiconductor structure recited in claim 10 wherein the polygon is a parallelogram.

16. A semiconductor structure, comprising:
a wafer;
a plurality of chips disposed on the wafer, each one of the chips having a linear array of a plurality of transistors, the linear array being at an oblique angle with respect to grid lines in the wafer separating the chips.

17. The semiconductor wafer recited in claim 16 wherein the angle is forty-five degrees, 30 degrees, or 60 degrees.

18. The semiconductor wafer recited in claim 17 wherein each one of the integrated circuit chips includes a plurality of transistors distributed along an axis at an oblique angle to a pair of opposing sides of the integrated circuit chip.

19. A semiconductor structure comprising: a polygon shaped semiconductor integrated circuit chip; and a plurality of transistors disposed on the integrated circuit chip and distributed along an elongated dimension of the polygon.
